(19) United States
(12) Patent Application Publication
(10) Pub. No.: US 2023/0167553 A1
(43) Pub. Date: Jun. 1, 2023

(54) PLASMA PROCESSING APPARATUS AND METHOD FOR USING PLASMA PROCESSING APPARATUS

(71) Applicant: Panasonic Intellectual Property Management Co., Ltd., Osaka (JP)

(72) Inventor: Tetsuhiro IWAI, Osaka (JP)

(21) Appl. No.: 18/057,799

(22) Filed: Nov. 22, 2022

(30) Foreign Application Priority Data
Nov. 30, 2021 (JP) 2021-194143
Nov. 30, 2021 (JP) 2021-194144

(51) Int. Cl. C23C 16/513; C23C 16/458

(52) U.S. Cl. CPC C23C 16/513; C23C 16/4583

(57) ABSTRACT

A plasma processing apparatus 10 includes: a stage 11 for placing an object to be processed; a chamber 12 housing the stage 11, and having a first opening 12a at a top; a first dielectric member 13 forming a first space Si in the chamber 12 by closing the first opening 12a, and having a second opening 13a; a second dielectric member 15 forming a second space S2, the second space communicating with the first space S1 via the second opening 13a and extending more upward than the first dielectric member 13; and first and induction coils 16 and 17 for generating a plasma for processing the object, the former provided above the first dielectric member 13 so as to extend from a central side toward an outer peripheral side of the first dielectric member 13, and the latter provided so as to surround the second dielectric member 15.

### CROSS REFERENCE TO RELATED APPLICATION

The present application is based on and claims priority under 35 U.S.C. § 119 with respect to the Japanese Patent Application Nos. 2021-194143 and 2021-194144 both filed on Nov. 30, 2021, of which entire contents are incorporated herein by reference into the present application.

### TECHNICAL FIELD

The present disclosure relates to a plasma processing apparatus and a method for using a plasma processing apparatus.

### BACKGROUND

Conventionally, a plasma processing apparatus that performs plasma processing on an object to be processed has been known as disclosed in Patent Literature 1 (JP2013-012761A). The plasma processing apparatus of Patent Literature 1 includes a stage for placing an object to be processed, a chamber housing the stage and having an opening at the top, a dielectric member forming a predetermined space in the chamber by closing the opening, and first and second induction coils for generating a plasma for processing the object to be processed, each provided above the dielectric member. In the predetermined space, the plasma processing on the object to be processed is performed using the plasma generated by the first and second induction coils.

However, in the plasma processing apparatus of Patent Literature 1, although the speed at which the object to be processed is plasma-etched (hereinafter, etching rate) is highly controllable, it is difficult to efficiently utilize the outputs of the first and second induction coils. This is due to the presence of the thick dielectric member between a predetermined space, which is a region where the plasma is generated, and the first and second induction coils. Under such circumstances, one of the aims of the present disclosure is to efficiently improve the controllability of the etching rate.

### SUMMARY

One aspect of the present disclosure relates to a plasma processing apparatus. The plasma processing apparatus includes: a stage for placing an object to be processed; a chamber housing the stage, and having a first opening at a top; a first dielectric member forming a first space in the chamber by closing the first opening, and having a second opening; a second dielectric member forming a second space, the second space communicating with the first space via the second opening and extending more upward than the first dielectric member; a first induction coil for generating a plasma for processing the object to be processed, the first induction coil provided above the first dielectric member so as to extend from a central side toward an outer peripheral side of the first dielectric member; and a second induction coil for generating a plasma for processing the object to be processed, the second induction coil provided so as to surround the second dielectric member.

Another aspect of the present disclosure relates to a method for using a plasma processing apparatus. The method is for using a plasma processing apparatus including: a stage for placing an object to be processed; a chamber housing the stage, and having a first opening at a top; a first dielectric member forming a first space in the chamber by closing the first opening, and having a second opening; a second dielectric member forming a second space, the second space communicating with the first space via the second opening and extending more upward than the first dielectric member; a first induction coil provided above the first dielectric member so as to extend from a central side toward an outer peripheral side of the first dielectric member; and a second induction coil provided so as to surround the second dielectric member. The method includes generating a plasma for processing the object to be processed, by supplying a source gas into the chamber, and applying a power to the first and second induction coils.

Another aspect of the present disclosure relates to a plasma processing apparatus. The plasma processing apparatus includes: a stage for placing an object to be processed; a chamber housing the stage, and having a first opening at a top; a first dielectric member forming a first space in the chamber by closing the first opening, and having a second opening; a first induction coil for generating a plasma for processing the object to be processed, the first induction coil provided above the first dielectric member so as to extend from a central side toward an outer peripheral side of the first dielectric member; and a projection forming a second space, and having at a top a dielectric window for optical measurement, the second space communicating with the first space via the second opening and extending more upward than the first dielectric member.

Another aspect of the present disclosure relates a method for using a plasma processing apparatus. The method is for using a plasma processing apparatus including: a stage for placing an object to be processed; a chamber housing the stage, and having a first opening at a top; a first dielectric member forming a first space in the chamber by closing the first opening, and having a second opening; a first induction coil for generating a plasma for processing the object to be processed, the first induction coil provided above the first dielectric member so as to extend from a central side toward an outer peripheral side of the first dielectric member; and a projection forming a second space, and having a dielectric window at a top, the second space communicating with the first space via the second opening and extending more upward than the first dielectric member. The method includes detecting information on the object to be processed, by an optical sensor from above the dielectric window through the second space.

According to the present disclosure, it is possible to efficiently improve the controllability of the etching rate. Furthermore, according to the present disclosure, it is possible to improve the optical measurement accuracy of an object to be processed.

### BRIEF DESCRIPTION OF THE DRAWINGS

FIG. 1 is a schematic cross-sectional view of a plasma processing apparatus of Embodiment 1.

FIG. 2 is a schematic plan view of a cover of Embodiment 1.

FIG. 3 is a schematic cross-sectional view of a plasma processing apparatus of Embodiment 2.

FIG. 4 is a schematic plan view of a cover of Embodiment 2.

FIG. 5 is a schematic cross-sectional view of a plasma processing apparatus of Embodiment 3.

FIG. 6 is a schematic plan view of a cover of Embodiment 3.

### DETAILED DESCRIPTION

Embodiments of a plasma processing apparatus and a method for using a plasma processing apparatus according to the present disclosure will be described below by way of examples. It is to be noted, however, that the present disclosure is not limited to the examples described below. In the description below, specific numerical values and materials are exemplified in some cases, but other numerical values and materials may be applied as long as the effects of the present disclosure can be achieved.

(Plasma Processing Apparatus)

A plasma processing apparatus according to one embodiment of the present disclosure (hereinafter sometimes referred to as a plasma processing apparatus A) is for performing plasma processing on an object to be processed. The plasma processing apparatus A may be, for example, a plasma etching apparatus, a plasma dicer, a plasma ashing apparatus, or a plasma CVD apparatus. The plasma processing apparatus A includes a stage, a chamber, a first dielectric member, a second dielectric member, a first induction coil, and a second induction coil.

The stage is a component element on which an object to be processed is placed. The stage may have a horizontal placement surface for placing the object to be processed. The stage may have a channel for flowing a coolant for cooling the object to be processed during plasma processing. The stage may have an electrostatic chuck system for chucking the object to be processed. The stage may have a lower electrode to be applied with a high-frequency power. The object to be processed may be, for example, a semiconductor substrate to be singulated by plasma etching. The semiconductor substrate includes a plurality of element regions and dicing regions defining the element regions. The element regions include, for example, a semiconductor layer and a wiring layer. By etching the dicing regions, element chips having a semiconductor layer and a wiring layer can be obtained. The object to be processed may be supported on a carrier, and in this state, may be placed on the stage. The carrier may be, for example, a resin sheet with the outer peripheral portion held by a frame.

The chamber houses the stage, and has a first opening at the top. The chamber may be formed in a hollow cylinder shape. The first opening may be open upward.

The first dielectric member forms a first space in the chamber by closing the first opening, and has a second opening. The first dielectric member may be formed in a plate shape having a horizontally extending region. The first space may be a space in which the stage is provided. The second opening may vertically pierce the first dielectric member. The second opening may be provided in the middle of the first dielectric member. The first dielectric member may be constituted of, for example, ceramics, such as quartz, alumina, and aluminum nitride.

The second dielectric member forms a second space communicating with the first space via the second opening and extending more upward than the first dielectric member. The second space makes it easy to control of the distribution of the plasma generated in the first space. The second dielectric member may be fitted into the second opening. The second dielectric member may be formed in a tubular shape extending vertically. The wall thickness of the second dielectric member may be smaller than the thickness of the first dielectric member. The second dielectric member may be constituted of, for example, ceramics, such as quartz, alumina, and aluminum nitride.

The first induction coil for generating a plasma for processing the object to be processed is provided above the first dielectric member (i.e., outside the first space) so as to extend from the central side toward the outer peripheral side of the first dielectric member. The first induction coil is provided, for example, above the first dielectric member in an annular region excluding a central region thereof, so as to face the first space. The magnetic field generated by the first induction coil mainly acts on the source gas in the first space via the first dielectric member.

The second induction coil for generating a plasma for processing the object to be processed is provided so as to surround the second dielectric member. The second induction coil is provided so as not to overlap the first induction coil in the vertical direction. By adjusting the power supplied to the first and second induction coils, the plasma distribution on the stage can be controlled with more flexibility. Therefore, it becomes easy to irradiate the plasma more uniformly onto the object to be processed. For example, when singulating a semiconductor substrate by plasma etching, the etching rate of the dicing regions can be controlled to be more uniform. At least part of the magnetic field generated by the second induction coil acts on the source gas in the first space and the second space via the second dielectric member. Since the second dielectric member is thinner than the first dielectric member, the magnetic field of the second induction coil efficiently acts on the source gas in the first space and the second space. Therefore, according to the plasma processing apparatus according to the present disclosure, it is possible to efficiently control the plasma distribution or the etching rate. For example, the etching rate can be efficiently made more uniform over the entire object to be processed.

The frequency of the power applied to the first induction coil and the frequency of the power applied to the second induction coil may be different from each other. In this case, the magnetic field generated by the first induction coil and the magnetic field generated by the second induction coil are unlikely to mutually interfere with each other. Therefore, the first and second induction coils can be controlled highly independently. The difference between the frequency of the first induction coil and the frequency of the second induction coil may be 10% or more of the higher of the two frequencies.

The frequency of the power applied to the first induction coil and the frequency of the power applied to the second induction coil may be equal to each other. In this case, it is easy to allow the first and second induction coils to share one power supply device.

The first dielectric member has a recess on the top surface. A least part of the first induction coil may be disposed in the recess. The portion of the first dielectric member where the recess is formed is thinner than the other portion. Therefore, the magnetic field of the first induction coil disposed in the recess efficiently acts on the source gas in the first space. The depth of the recess is not limited, but may be, for example, 25% to 45% of the maximum thickness of the first dielectric member. When the first induction coil is formed in a spiral shape, the recess may be formed in an annular shape substantially concentric with the first induction coil.

The second induction coil is provided so as to extend vertically along the second dielectric member. In this case, the second induction coil may be formed in a helical shape surrounding the second dielectric member.

A plasma processing apparatus according to another embodiment of the present disclosure (hereinafter sometimes referred to as a plasma processing apparatus B) is for performing plasma processing on an object to be processed. The plasma processing apparatus B may be, for example, a plasma etching apparatus, a plasma dicer, a plasma ashing apparatus, or a plasma CVD apparatus. The plasma processing apparatus B includes a stage, a chamber, a first dielectric member, a first induction coil, and a projection.

The stage may be similar to the stage of the plasma processing apparatus A.

The chamber may be similar to the chamber of the plasma processing apparatus A.

The first dielectric member may be similar to the first dielectric member of the plasma processing apparatus A.

The first induction coil may be similar to the first induction coil of the plasma processing apparatus A.

The projection forms a second space communicating with the first space via the second opening and extending more upward than the first dielectric member. The second space makes it easy to control of the distribution of the plasma generated in the first space. The projection may be fitted into the second opening. The projection may be formed in a tubular shape extending vertically. The wall thickness of the projection may be smaller than the thickness of the first dielectric member. The projection may be constituted of, for example, a dielectric member, and may be constituted of another material. The projection has at the top a dielectric window for optical measurement. The dielectric window is transparent to light, and may be made of quartz, for example. The dielectric window is located more upward than the first dielectric member. That is, the dielectric window is located away from the first space where plasma processing is performed. Therefore, reaction products generated when plasma processing is performed in the first space are less likely to adhere to the dielectric window. Hence, the optical measurement through the dielectric window of the object to be processed can be performed with high accuracy.

The dielectric window may have a thickness Tw smaller than a thickness T1 of the first dielectric member. Even with a thin thickness, the dielectric window, which is small in area, is unlikely to be damaged by atmospheric pressure. According to this configuration, the optical measurement through the dielectric window of the object to be processed can be performed with higher accuracy. The T2 may be, for example, 20% or more and 50% or less of the T1.

The projection may have a height larger than a diameter of the projection. According to this configuration, the second space is long in the vertical direction, and reaction products generated in the first space hardly reach the dielectric window. Therefore, the dielectric window is much less likely to become dirty, and the accuracy of the optical measurement of the object to be processed can be further improved. The dielectric window may be installed at a position higher than the tops of the first induction coil and the second induction coil. For example, the dielectric window may be installed at a position which is not shielded by a cover covering the first induction coil and the second induction coil. This allows for easy optical measurement without space limitation.

The plasma processing apparatus B may further include an optical sensor for detecting information on the object to be processed. The optical sensor is provided above the dielectric window. The optical sensor may be an infrared sensor, but is not limited thereto. The information on the object to be processed is, for example, the thickness of at least part of the object to be processed and/or the temperature of the object to be processed.

The plasma processing apparatus B may further include a second induction coil for generating a plasma for processing the object to be processed. The second induction coil is provided so as to surround the projection. The second induction coil is provided so as not to overlap the first induction coil in the vertical direction. According to this configuration, by adjusting the power supplied to the first and second induction coils, the plasma distribution on the stage can be controlled with more flexibility. Therefore, it becomes easy to irradiate the plasma more uniformly onto the object to be processed. For example, when singulating a semiconductor substrate by plasma etching, the etching rate of the dicing regions (the speed at which the object to be processed is plasma-etched) can be controlled to be more uniform.

The plasma processing apparatus B may further include a first gas introduction path for supplying a first source gas into a region facing the first induction coil in the first space, and a second gas introduction path for supplying a second source gas into a region facing the second induction coil in the first space or the second space. According to this configuration, the first source gas is supplied in the vicinity of the first induction coil, and the second source gas is supplied in the vicinity of the second induction coil. Therefore, a plasma containing each source gas can be highly efficiently generated by each induction coil. The first source gas and the second source gas may be of the same type or different types.

(Method for Using Plasma Processing Apparatus)

A method for using a plasma processing apparatus according to one embodiment of the present disclosure (hereinafter sometimes referred to as a use method A) is for using the above-described plasma processing apparatus and includes a step of generating a plasma for processing the object to be processed, by supplying a source gas into the chamber, and applying a power to the first and second induction coils. The use method A usually includes a step of placing an object to be processed, on the stage, and a step of processing or etching the object to be processed, with the generated plasma. For example, the use method A may include a step of singulating a semiconductor substrate, which is the object to be processed, by plasma etching. The plasma may be, for example, a plasma containing a fluorine-containing gas, but is not limited thereto. According to the use method A, the etching rate can be controlled efficiently.

The frequency of the power applied to the first induction coil and the frequency of the power applied to the second induction coil may be different from each other. In this case, the magnetic field generated by the first induction coil and the magnetic field generated by the second induction coil are unlikely to mutually interfere with each other. Therefore, the first and second induction coils can be controlled highly independently.

The frequency of the power applied to the first induction coil and the frequency of the power applied to the second induction coil may be equal to each other. In this case, it is easy to allow the first and second induction coils to share one power supply device.

A method for using a plasma processing apparatus according to another embodiment of the present disclosure (hereinafter sometimes referred to as a use method B) is for using the above-described plasma processing apparatus and includes a step of detecting information on the object to be processed, by the optical sensor from above the dielectric window through the second space. The information on the object to be processed is, for example, the thickness of at least part of the object to be processed and/or the temperature of the object to be processed. According to the use method B, the optical measurement through the dielectric window of the object to be processed can be performed with high accuracy.

As describe above, according to the present disclosure, the etching rate can be efficiently controlled. Moreover, according to the present disclosure, the etching rate can be efficiently made more uniform over the entire object to be processed. Furthermore, according to the present disclosure, the dielectric window can be prevented from becoming dirty, and thus, the optical measurement accuracy of the object to be processed can be improved.

In the following, examples of the plasma processing apparatus and the method for using a plasma processing apparatus according to the present disclosure will be specifically described with reference to the drawings. The components and processes as described above can be applied to the components and processes of the below-described examples of the plasma processing apparatus and the method for using a plasma processing apparatus. The components and processes of the below-described examples of the plasma processing apparatus and the method for using a plasma processing apparatus can be modified based on the description above. The matters as described below may be applied to the above embodiments. Of the components and processes of the below-described examples of the plasma processing apparatus and the method for using a plasma processing apparatus, the components and processes which are not essential to the plasma processing apparatus and the method for using a plasma processing apparatus according to the present disclosure may be omitted. The figures below are schematic and not intended to accurately reflect the shape and the number of the actual members.

### Embodiment 1

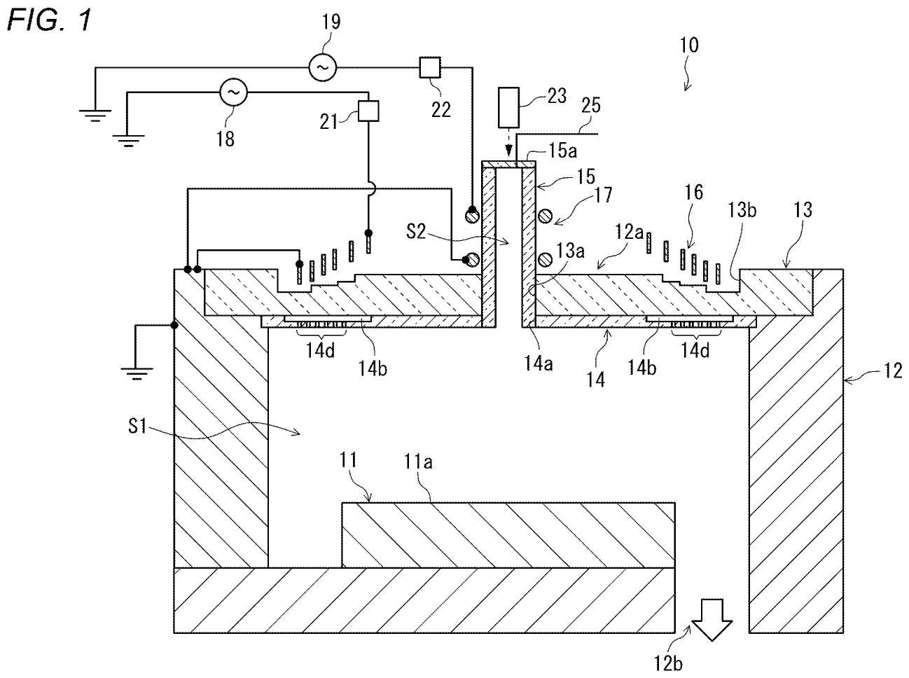

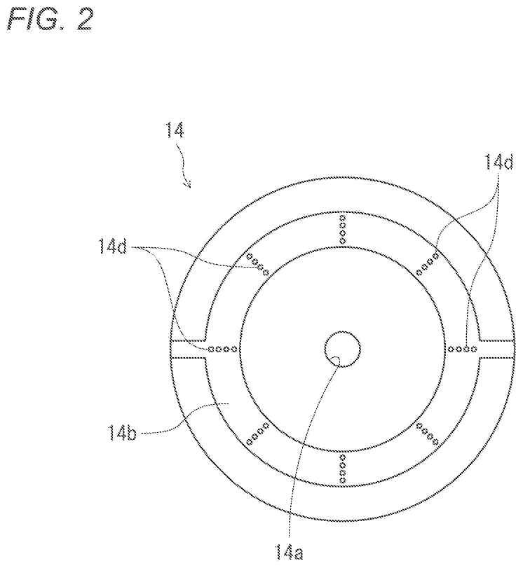

Embodiment 1 of the present disclosure will be described. A plasma processing apparatus 10 of the present embodiment is for performing plasma processing on an object to be processed (e.g., a semiconductor substrate). The plasma processing apparatus 10 of the present embodiment is a plasma dicer, but is not limited thereto. As illustrated in FIGS. 1 and 2, the plasma processing apparatus 10 includes a stage 11, a chamber 12, a first dielectric member 13, a cover 14, a second dielectric member 15, a first induction coil 16, a second induction coil 17, a first high-frequency power source 18, a second high-frequency power source 19, and an optical sensor 23.

The stage 11 is a component element on which an object to be processed is placed. The stage 11 has a horizontal placement surface 11a for placing the object to be processed. The stage 11 has a channel (not shown) for flowing a coolant for cooling the object to be processed during plasma processing. The stage 11 has an electrostatic chuck system (not shown) for chucking the object to be processed. The stage 11 has a lower electrode (not shown) to be applied with a high-frequency power.

The chamber 12 houses the stage 11 and has a first opening 12a at the top. The chamber 12 is formed in a hollow cylindrical shape, but is not limited thereto. The first opening 12a is open upward. The chamber 12 is provided circumferentially outward from the stage 11, and has an exhaust port 12b for exhausting the source gas used for plasma processing (the first and/or second source gas). An exhaust device (not shown) is connected to the exhaust port 12b. The chamber 12 is constituted of a conductive member (e.g., metal).

The first dielectric member 13 forms a first space S1 in the chamber 12 by closing the first opening 12a, and has a second opening 13a. The first dielectric member 13 is formed in a plate shape having a horizontally extending region. The first space S1 is a space in which the stage 11 is provided. The second opening 13a vertically pierces the first dielectric member 13. The second opening S2 is provided in the middle of the first dielectric member 13. The first dielectric member 13 has a recess 13b at the top. The first dielectric member 13 is constituted of quartz, but is not limited thereto.

The cover 14 is installed so as to cover the lower surface of the first dielectric member 13. The cover 14 includes a first gas introduction path 14b for supplying a first source gas into a region facing the first induction coil 16 in the first space S1. The first gas introduction path 14b is constituted of a groove or recess formed on the upper surface of the cover 14. The first gas introduction path 14b communicates with outside the chamber 12 and communicates with the first space S1 via a first gas hole 14d. A plurality of the first gas holes 14d are provided at intervals in the circumferential direction (see FIG. 2). The plurality of the first gas holes 14d are provided at intervals in the radial direction (the left-right direction in FIG. 1). The first gas introduction path 14b is formed between the cover 14 and the first dielectric member 13. To the first gas introduction path 14b, a first source gas is supplied from a gas source (not shown). The cover 14 has a third opening 14a overlapping the second opening 13a. The third opening 14a is provided in the middle of the cover 14. The cover 14 is constituted of aluminum nitride, but is not limited thereto.

The second dielectric member 15 forms a second space S2 communicating with the first space S1 via the second opening 13a and the third opening 14a and extending more upward than the first dielectric member 13. The second dielectric member 15 is fitted into the second opening 13a and the third opening 14a. The second dielectric member 15 is formed in a tubular shape extending vertically. The wall thickness of the second dielectric member 15 is smaller than the thickness of the first dielectric member 13. The height (vertical dimension) of the second dielectric member 15 is greater than the diameter of the second dielectric member 15. The second dielectric member 15 is constituted of aluminum nitride, but is not limited thereto. The second dielectric member 15 is one example of the projection.

To the second space S2 formed by the second dielectric member 15, a gas pipe 25 for supplying a second source gas to a region facing the second induction coil 17 in the second space S2 is connected. To the gas pipe 25, the second source gas is supplied from a gas source (not shown). The gas pipe 25 is one example of the second gas introduction path.

The second dielectric member 15 has at the top a dielectric window 15a for optical measurement. The dielectric window 15a transmits light emitted by or from the optical sensor 23, the object to be processed placed on the stage 11, or the plasma. The thickness (vertical dimension) of the dielectric window 15a is smaller than the thickness (vertical dimension) of the first dielectric member 13. The maximum thickness of the dielectric window 15a may be smaller than the minimum thickness of first dielectric member 13. The dielectric window 15a may be integrated with or separate from the tubular portion of the second dielectric member 15.

The first induction coil 16 for generating a plasma for processing the object to be processed is provided above the first dielectric member 13 so as to extend from the central side toward the outer peripheral side of the first dielectric member 13. The first induction coil 16 is constituted of one or more conductors each spirally extending in the circumferential direction. Part of the first induction coil 16 on the outer peripheral side is disposed in the recess 13b formed in the first dielectric member 13. The first induction coil 16, when applied with a high-frequency power from the first high-frequency power source 18, generates a magnetic field. This magnetic field acts on the source gas (first and/or second source gas) in the first space S1 via the first dielectric member 13, to generate a plasma.

The second induction coil 17 for generating a plasma for processing the object to be processed is provided so as to surround the second dielectric member 15. The second induction coil 17 is helically wound around the second dielectric member 15 and extends vertically along the second dielectric member 15. The second induction coil 17 is provided more circumferentially inward than the first induction coil 16. The second induction coil 17, when applied with a high-frequency power from the second high-frequency power source 19, generates a magnetic field. This magnetic field acts on the source gas (first and/or second source gas) in the first space S1 and/or the second space S2 via the second dielectric member 15, to generate a plasma.

The first high-frequency power source 18 supplies a high-frequency power (e.g., an AC power of 3 to 30 MHz) to the first induction coil 16. The first high-frequency power source 18 is connected to one end of the first induction coil 16 via a first matcher 21, such as a variable capacitor. The other end of the first induction coil 16 is grounded via the electrically conductive chamber 12.

The second high-frequency power source 19 supplies a high-frequency power (e.g., an AC power of 3 to 30 MHz) to the second induction coil 17. The second high-frequency power source 19 is connected to one end of the second induction coil 17 via a second matcher 22, such as a variable capacitor. The other end of the second induction coil 17 is grounded via the electrically conductive chamber 12.

The frequency of the power of the first high-frequency power source 18 (the power applied to the first induction coil 16) and the frequency of the power of the second high-frequency power source 19 (the power applied to the second induction coil 17) are different from each other. The two frequencies may be equal to each other.

The optical sensor 23 for detecting information on the object to be processed is provided above the dielectric window 15a. The optical sensor 23 detects the information on the object to be processed, by irradiating a light onto the object to be processed, through the dielectric window 15a, the second space S2, and the first space S1, and receiving the light reflected from the object. Alternatively, the optical sensor 23 detects the information on the object to be processed, by receiving a light emitted by the object to be processed, through the dielectric window 15a, the second space S2, and the first space S1. Alternatively, the optical sensor 23 detects the information on the object to be processed and the plasma, by receiving a light emitted by the plasma, through the dielectric window 15a, the second space S2, and the first space S1. The optical sensor 23 is constituted of, for example, an infrared sensor, but is not limited thereto. The information on the object to be processed is, for example, the thickness of at least part of the object to be processed and/or the temperature of the object to be processed. The information on the plasma is, for example, the composition of the plasma.

The light reflected from the object to be processed, the light emitted by the object to be processed, or the light emitted by the plasma reaches the optical sensor 23 via the first space S1, the second space S2, and the dielectric window 15a. In this case, by increasing the height dimension of the second space S2, that is, by increasing the height dimension of the dielectric member 15, the ratio of the optical path in the atmosphere (specifically, the optical path between the dielectric window 15a and the optical sensor 23) to the entire optical path for these lights to reach the optical sensor 23 can be reduced. This can improve the measurement accuracy by the optical sensor 23. In particular, this can improve the measurement accuracy when measuring the temperature of the object to be processed using an infrared sensor.

—Method for Using Plasma Processing Apparatus—

A method for using a plasma processing apparatus of the present embodiment will be described. The method is for using the above-described plasma processing apparatus 10, and includes generating a plasma for processing an object to be processed, by supplying a source gas (first and second source gases) into the chamber 12, and applying a power to the first and second induction coils 16 and 17, to process the object to be processed. The method includes detecting information on the object to be processed, by the optical sensor 23 from above the dielectric window 15a. As a result of these, it is possible to appropriately adjust the power applied to the first and second induction coils 16 and 17, based on the information on the object to be processed. For example, the power applied to the first and second induction coils 16 and 17 can be adjusted, based on the thickness of at least part of the object to be processed. When singulating a semiconductor substrate by plasma etching, the etching rate of the dicing regions can be controlled to be more uniform as much as possible over the entire surface of the semiconductor substrate.

### Embodiment 2

Embodiment 2 of the present disclosure will be described. The plasma processing apparatus 10 of the present embodiment differs from that of Embodiment 1 in the configuration of the cover 14. In the following, the difference from Embodiment 1 will be mainly described.

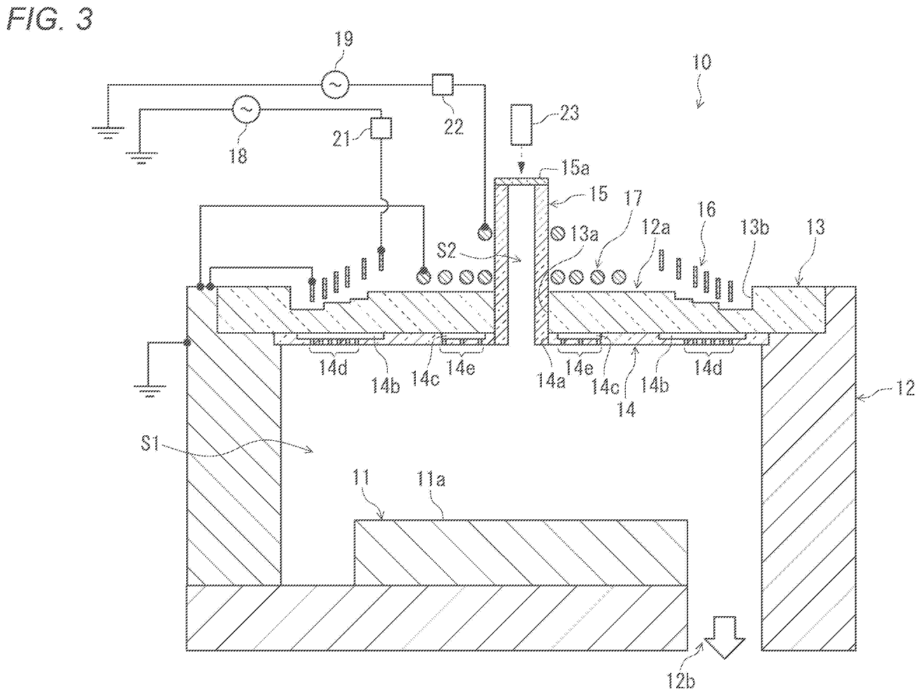

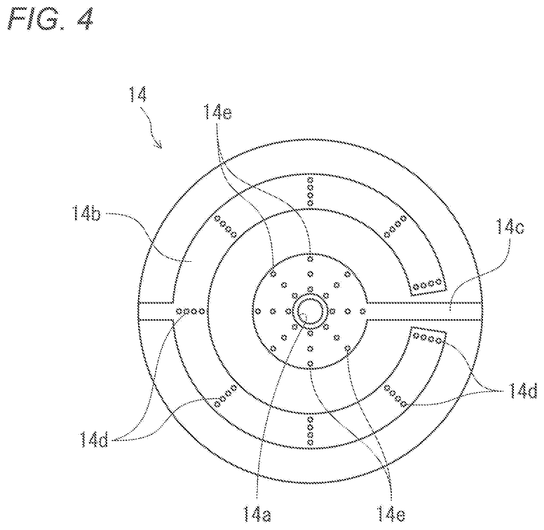

As illustrated in FIGS. 3 and 4, in addition to the first gas introduction path 14b, the cover 14 has a second gas introduction path 14c for supplying a second source gas to a region facing the second induction coil 17 in the first space S1. The second gas introduction path 14c is constituted of a groove or recess formed on the upper surface of the cover 14. The second gas introduction path 14c is formed, for example, so as to be surrounded by the annular first gas introduction path 14b. The second gas introduction path 14c communicates with outside the chamber 12 and communicates with the first space S1 via a second gas hole 14e. A plurality of the second gas holes 14e are provided at intervals in the circumferential direction (see FIG. 4). A plurality of the second gas holes 14e are provided at intervals in the radial direction (the left-right direction in FIG. 3). The second gas introduction path 14c is formed between the cover 14 and the first dielectric member 13. To the second gas introduction path 14c, the second source gas is supplied from a gas source (not shown).

The second induction coil 17 has a portion extending vertically along the second dielectric member 15 and a portion extending horizontally along the first dielectric member 13. The former is formed in a helical shape extending in the vertical direction, and the latter is formed in a coil shape (spiral shape) extending in the horizontal direction.

### Embodiment 3

Embodiment 3 of the present disclosure will be described. The plasma processing apparatus 10 of the present embodiment differs from that of Embodiment 2 in that a tubular member 24 is further provided. In the following, the difference from Embodiment 2 will be mainly described.

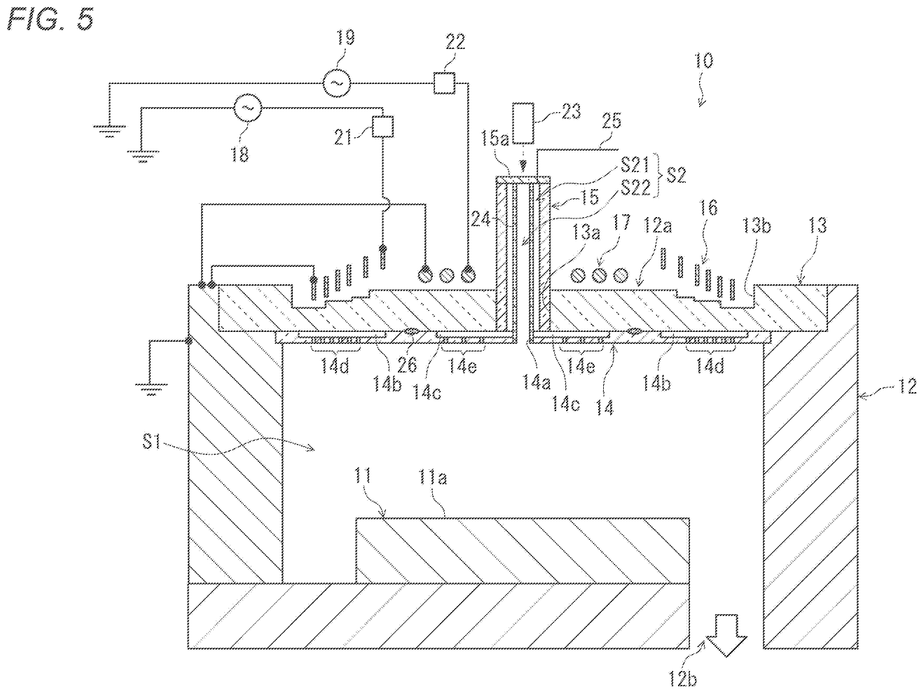

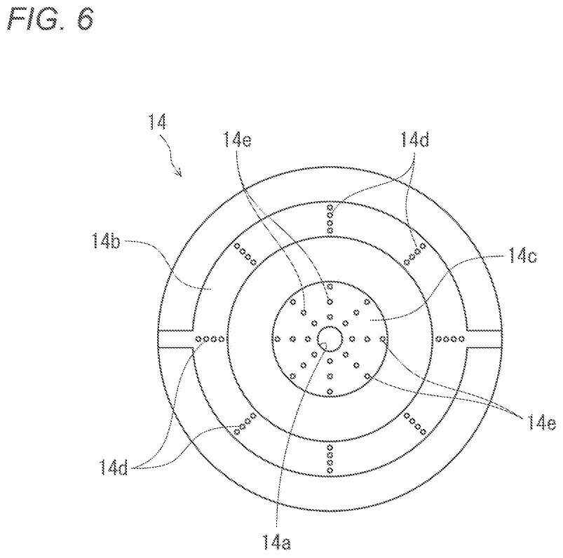

As illustrated in FIGS. 5 and 6, the plasma processing apparatus 10 includes the tubular member 24 provided inside the second dielectric member 15. The tubular member 24 partitions the second space S2 into an outer space S21 and an inner space S22. The outer space S21 communicates with the second gas introduction path 14c provided in the cover 14. To the outer space S21, the second source gas is supplied through the gas pipe 25 from a gas source (not shown). The gas pipe 25 may supply the second source gas to the outer space S21 from a position higher than the tops of the first and second induction coils 16 and 17 so that the gas pipe 25 is not affected by the second induction coil 17. The inner space S22 communicates with the first space S1. The inner space S22 can be used to generate a plasma. The inner space S22 can be used to detect information on the object to be processed, by the optical sensor 23 from above the dielectric window 15a. The cylindrical member 24 is fitted into the third opening 14a of the cover 14. The cylindrical member 24 is made of aluminum nitride, but is not limited thereto. The second dielectric member 15 of the present embodiment is made of quartz. The first gas introduction path 14b and the second gas introduction path 14c are partitioned from each other by an O-ring 26. By partitioning the first gas introduction path 14b from the second gas introduction path 14c, the amount of each of the first and second source gases to be supplied can be controlled more accurately.

The present disclosure is applicable to a plasma processing apparatus and a method of using a plasma processing apparatus.

### REFERENCE NUMERALS

10: plasma processing apparatus
11: stage
11a: placement surface
12: chamber
12a: first opening
12b: exhaust port
13: first dielectric member
13a: second opening
13b: recess
14: cover
14a: third opening
14b: first gas introduction path
14c: second gas introduction path
14d: first gas hole
14e: second gas hole
15: second dielectric member
15a: dielectric window
16: first induction coil
17: second induction coil
18: first high-frequency power source
19: second high-frequency power source
21: first matcher
22: second matcher
23: optical sensor
24: tubular member
25: gas pipe (second gas introduction path)
26: O-ring
S1: first space
S2: second space
S21: outer space
S22: inner space

What is claimed is:

1. A plasma processing apparatus, comprising:
a stage for placing an object to be processed;
a chamber housing the stage, and having a first opening at a top;
a first dielectric member forming a first space in the chamber by closing the first opening, and having a second opening;
a second dielectric member forming a second space, the second space communicating with the first space via the second opening and extending more upward than the first dielectric member;
a first induction coil for generating a plasma for processing the object to be processed, the first induction coil provided above the first dielectric member so as to extend from a central side toward an outer peripheral side of the first dielectric member; and
a second induction coil for generating a plasma for processing the object to be processed, the second induction coil provided so as to surround the second dielectric member.

2. The plasma processing apparatus according to claim 1, wherein a frequency of a power applied to the first induction coil and a frequency of a power applied to the second induction coil are different from each other.

3. The plasma processing apparatus according to claim 1, wherein a frequency of a power applied to the first induction coil and a frequency of a power applied to the second induction coil are equal to each other.

4. The plasma processing apparatus according to claim 1, wherein
the first dielectric member has a recess on a top surface, and
at least part of the first induction coil is disposed in the recess.

5. The plasma processing apparatus according to claim 1, wherein the second induction coil is provided so as to extend vertically along the second dielectric member.

6. A method for using a plasma processing apparatus, the plasma processing apparatus including:
a stage for placing an object to be processed;
a chamber housing the stage, and having a first opening at a top;
a first dielectric member forming a first space in the chamber by closing the first opening, and having a second opening;
a second dielectric member forming a second space, the second space communicating with the first space via the second opening and extending more upward than the first dielectric member;
a first induction coil provided above the first dielectric member so as to extend from a central side toward an outer peripheral side of the first dielectric member; and
a second induction coil provided so as to surround the second dielectric member, the method comprising:
generating a plasma for processing the object to be processed, by supplying a source gas into the chamber, and applying a power to the first and second induction coils.

7. The method for using a plasma processing apparatus according to claim 6, wherein a frequency of a power applied to the first induction coil and a frequency of a power applied to the second induction coil are different from each other.

8. The method for using a plasma processing apparatus according to claim 6, wherein a frequency of a power applied to the first induction coil and a frequency of a power applied to the second induction coil are equal to each other.

9. A plasma processing apparatus, comprising:
a stage for placing an object to be processed;
a chamber housing the stage, and having a first opening at a top;
a first dielectric member forming a first space in the chamber by closing the first opening, and having a second opening;
a first induction coil for generating a plasma for processing the object to be processed, the first induction coil provided above the first dielectric member so as to extend from a central side toward an outer peripheral side of the first dielectric member; and
a projection forming a second space, and having at a top a dielectric window for optical measurement, the second space communicating with the first space via the second opening and extending more upward than the first dielectric member.

10. The plasma processing apparatus according to claim 9, wherein the dielectric window has a thickness smaller than a thickness of the first dielectric member.

11. The plasma processing apparatus according to claim 9, wherein the projection has a height larger than a diameter of the projection.

12. The plasma processing apparatus according to claim 9, further comprising an optical sensor for detecting information on the object to be processed, the optical sensor provided above the dielectric window.

13. The plasma processing apparatus according to claim 9, further comprising a second induction coil for generating a plasma for processing the object to be processed, the second induction coil provided so as to surround the projection.

14. The plasma processing apparatus according to claim 13, further comprising:
a first gas introduction path for supplying a first source gas into a region facing the first induction coil in the first space; and
a second gas introduction path for supplying a second source gas into a region facing the second induction coil in the first space or the second space.

15. A method for using a plasma processing apparatus, the plasma processing apparatus including:
a stage for placing an object to be processed;
a chamber housing the stage, and having a first opening at a top;
a first dielectric member forming a first space in the chamber by closing the first opening, and having a second opening;
a first induction coil for generating a plasma for processing the object to be processed, the first induction coil provided above the first dielectric member so as to extend from a central side toward an outer peripheral side of the first dielectric member; and
a projection forming a second space, and having a dielectric window at a top, the second space communicating with the first space via the second opening and extending more upward than the first dielectric member, the method comprising:
detecting information on the object to be processed, by an optical sensor from above the dielectric window through the second space.
